(19) United States
(12) Patent Application Publication
(10) Pub. No.: US 2018/0040457 A1
(43) Pub. Date: Feb. 8, 2018

(54) SURFACE TREATMENT FOR IMPROVEMENT OF PARTICLE PERFORMANCE

(71) Applicant: Applied Materials, Inc., Santa Clara, CA (US)

(72) Inventor: Banqiu WU, San Jose, CA (US)

(73) Assignee: Applied Materials, Inc., Santa Clara, CA (US)

(21) Appl. No.: 15/671,862

(22) Filed: Aug. 8, 2017

Related U.S. Application Data
(60) Provisional application No. 62/372,145, filed on Aug. 8, 2016.

(51) Int. Cl. H01J 37/32; H01L 21/67

(52) U.S. Cl. CPC H01J 37/321; H01L 21/67069; H01J 37/3244; H01J 37/32651; H01J 2237/334; H01J 2237/3321

(57) ABSTRACT

Implementations of the disclosure provide a surface treatment process for chamber components. In one implementation, the chamber component includes a crystalline body comprising machined surfaces including at least a reflowed surface layer formed in a plasma treatment chamber by placing the body on a pedestal disposed within the plasma chamber, maintaining a pressure in the plasma chamber at 0.1-100 mTorr, flowing a gas into the plasma chamber at a flow rate of 10-500 sccm, applying an RF power to an inductive coil of the plasma chamber to form a plasma from the gas in the plasma chamber, the RF power of 300 Watts is applied at a frequency of 10 kHz to 160 MHz, and applying an RF bias power of 100 Watts at a frequency of 10 kHz to 160 MHz to the pedestal to bombard the body with ions from the plasma for 10-100 hours.

### CROSS-REFERENCE TO RELATED APPLICATIONS

This application claims priority to U.S. provisional patent application Ser. No. 62/372,145, filed Aug. 8, 2016, which is herein incorporated by reference.

### FIELD

Implementations of the present disclosure generally relate to methods of pre-treating a chamber component and a surface-treated component for use in a semiconductor process chamber.

### BACKGROUND

A substrate processing chamber is used to process a substrate such as for example, a semiconductor wafer or display, in an energized process gas. The processing chamber typically includes an enclosure wall that encloses a process zone into which a gas is introduced and energized. The chamber may be used to deposit material on the substrate by chemical or physical vapor deposition, etch material from a substrate, implant material on a substrate, or convert substrate layers such as by oxidizing layers or forming nitrides. The chamber typically includes a number of internal chamber components such as, for example, a substrate support, gas distributor, gas energizer, and different types of liners and shields. For example, the liners and shields can be cylindrical members surrounding the substrate to serve as focus rings to direct and contain plasma about the substrate, deposition rings that prevent deposition on underlying components or portions of the substrate, substrate shields, and chamber wall liners.

Ceramic materials are often used to form the internal chamber components, especially those components that are exposed to the energized gas or plasma, and consequently, are subject to high temperatures and erosion. Ceramic materials such as alumina and silica are crystalline whereas silica glasses have no long range order. Ceramics typically exhibit good resistance to erosion by the energized gases, and consequently, do not have to be replaced as often as metal alloys. Ceramic components can also withstand high temperatures without thermal degradation.

Chamber components formed from ceramic materials typically have machined surfaces with microcracks, pits, peaks or sharp grain boundaries. The tips of such microcracks, pits, or peaks are more apt to break off during processing, which can contaminate the semiconductor substrate being processed and increase defect rates.

Therefore, there is a need in the art to provide an improved surface treatment process for chamber components for particle reduction in the semiconductor process chamber.

### SUMMARY

Implementations of the present disclosure provide a surface-treated component for use in a semiconductor process chamber and improved surface treatment processes for chamber components used in a semiconductor process chamber. In one implementation, the chamber component includes a crystalline body comprising machined surfaces facing a processing region of the process chamber, wherein the machined surfaces comprises at least a reflowed surface layer formed in a plasma treatment chamber by placing the body on a pedestal disposed within the plasma chamber, maintaining a pressure in the plasma chamber at 0.5 mTorr to 100 mTorr, flowing a gas into the plasma chamber at a flow rate of 10 sccm to 500 sccm, applying an RF power to an inductive coil of the plasma chamber to form a plasma from the gas in the plasma chamber, wherein the RF power is applied on the range of 300 Watts at a frequency of 10 kHz to 160 MHz, and while applying the RF power to the inductive coil, applying an RF bias power to the pedestal to bombard the body with ions from the plasma, wherein the RF bias power is applied on the range of 30 to 500 Watts at a frequency of 10 kHz to 160 MHz, and the body is bombarded with ions for about 10 hours to about 100 hours.

In another implementation, a method of fabricating a component for use in a process chamber is provided. The method includes providing a crystalline body onto a pedestal disposed within a plasma chamber, the body having a first machined surface to interface a component of the process chamber and a second machined surface facing a processing region of the process chamber, maintaining a pressure in the plasma chamber at 0.5 mTorr to 100 mTorr, flowing a gas into the plasma chamber at a flow rate of 10 sccm to 500 sccm, applying an RF power to an inductive coil of the plasma chamber to form a plasma from the gas in the plasma chamber, wherein the RF power is applied on the range of 100 Watts to 2000 Watts at a frequency of 10 kHz to 60 MHz, and while applying the RF power to the inductive coil, applying an RF bias power to the pedestal to bombard the body with ions from the plasma so that a portion at surface of the crystalline body is melted and reflowed to form a reflowed surface layer, wherein the RF bias power is applied on the range of 20 Watts to 500 Watts at a frequency of 10 kHz to 60 MHz, and the body is bombarded with ions for about 10 hours to about 100 hours.

In yet another implementation, the method includes bombarding machined surfaces of a crystalline body disposed on a pedestal with ions from a plasma in a plasma chamber to melt a portion at surface of the crystalline body to form a reflowed surface layer having a thickness of about 0.1 μm to 50 μm, wherein the bombarding machined surfaces of the crystalline body with ions is performed by maintaining a pressure in the plasma chamber at range of 0.5 to 100 mTorr, flowing a gas into the plasma chamber at a flow rate of 10 sccm to 500 sccm, applying an RF source power on the range of 100 to 2000 Watts at a frequency of 10 kHz to 160 MHz to form a plasma from the gas, and applying an RF bias power on the range of 20 to 500 Watts at a frequency of 10 kHz to 160 MHz to the pedestal for about 10 hours to about 200 hours.

### BRIEF DESCRIPTION OF THE DRAWINGS

Implementations of the present disclosure, briefly summarized above and discussed in greater detail below, can be understood by reference to the illustrative implementations of the disclosure depicted in the appended drawings. It is to be noted, however, that the appended drawings illustrate only typical implementations of this disclosure and are therefore not to be considered limiting of its scope, for the disclosure may admit to other equally effective implementations.

FIG. 1 is a schematic, cross sectional view of a semiconductor substrate process system having one or more chamber components that are treated with an treatment process in accordance with implementations of the disclosure.

FIG. 2 illustrates a method for processing a chamber component according to implementations of the disclosure.

FIG. 3A shows a laser microscope (LM) image of an untreated surface of a chamber cover ring.

FIG. 3B shows a LM image of an ion bombardment treated surface of the chamber cover ring.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

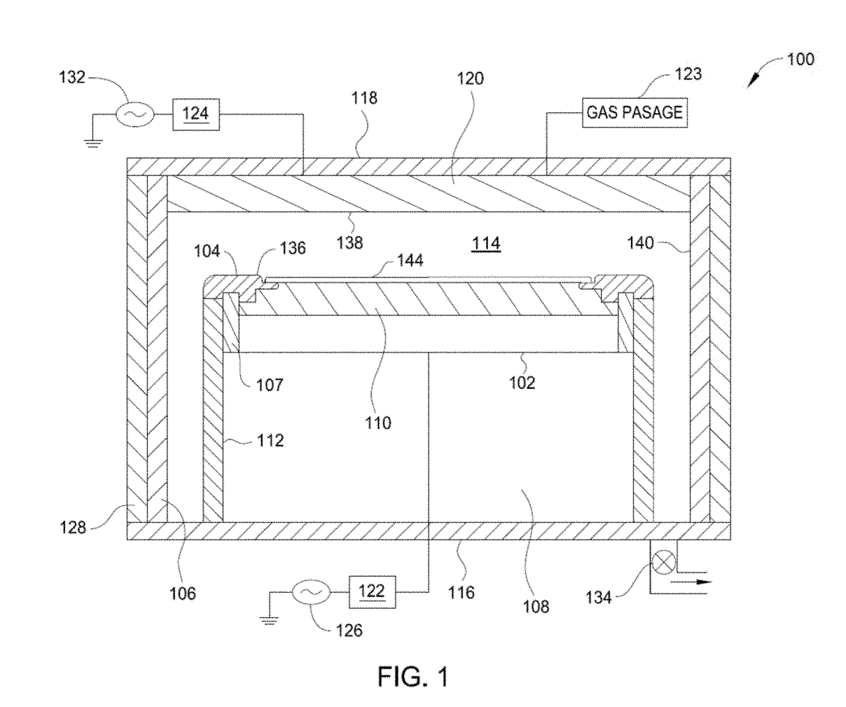

FIG. 1 is a schematic, cross sectional view of a substrate process chamber 100 having one or more chamber components that are treated with an treatment process in accordance with implementations of the disclosure. The illustrated process chamber 100 is suitable for etching, chemical vapor deposition (CVD), and the like. In one implementation, the process chamber is a plasma treatment chamber. The process chamber 100 may be used for etching a photomask. The process chamber 100 generally includes a cylindrical side wall 128, a circular bottom wall 116, and a top wall or lid 118. The process chamber 100 may be utilized alone or as a processing module of an integrated semiconductor substrate processing system or cluster tool. A pedestal 108 is disposed in the process chamber 100 to support a semiconductor wafer or workpiece 144. The pedestal 108 is disposed below an anode electrode 120 mounted to the bottom of the lid 118. The anode electrode 120 may be perforated to function as a gas inlet through which process gases enter the process chamber 100 (e.g., the anode electrode 120 may be a showerhead) from a gas source 123.

The pedestal 108 may be biased by a DC power supply (now shown). A radio frequency (RF) power source 126 can be optionally coupled to the pedestal 108 through a matching network 122. The anode electrode 120 can be coupled to an RF power source 132 through a matching network 124. The interior of the process chamber 100 is a high vacuum vessel that is coupled through a throttle valve (not shown) to a vacuum pump 134.

During processing, the semiconductor wafer 144 is placed on the pedestal 108 and the interior of the process chamber 100 is pumped down to a near vacuum environment. One or more processing gases is/are supplied through the anode electrode 120 (e.g., showerhead) into a processing region 114. The processing gas or gases is/are ignited into a plasma by applying power from the RF power source 132 to the anode electrode 120 and/or the RF power source 126 to the pedestal 108 while applying power from a bias source (not shown) to bias the pedestal 108. The formed plasma may be used to etch feature(s) in the semiconductor wafer 144 during processing and then pumped out of the process chamber 100 through the vacuum pump 134. It is to be understood that other components of the process chamber 100 have been omitted for purposes of clarity by example.

During processing, the plasma may extend not only to the semiconductor wafer 144, but also to the chamber walls. To protect the chamber walls from the plasma, the process chamber 100 can include a liner 106. The liner 106 can be removable in order to be cleaned and/or replaced.

The pedestal 108 generally includes a cathode 102, a ring assembly 104, a dielectric shield 107, and a support insulator 112. The cathode 102 may optionally include an electrostatic chuck (ESC) or a mechanical chuck 110 for clamping the semiconductor wafer 144 against the cathode 102. The cathode 102 can be biased by a DC power source (not shown) and optionally the RF power source 126.

To maximize the concentration of reactive species and charged particles at the surface of the semiconductor wafer 144, RF current flow between the plasma and the cathode 102 should be concentrated in the area occupied by the semiconductor wafer 144. Thus, surfaces of the cathode 102 that are not covered by the semiconductor wafer 144 are covered by dielectric material, including the ring assembly 104 and the dielectric shield 107. The dielectric shield 107 includes a cylinder of dielectric material that covers a side surface of the cathode 102. The ring assembly 104 rests on and overlaps a portion of the top surface of the cathode 102 that is outside of the perimeter of the semiconductor wafer 144. The support insulator 112 functions to electrical isolate the substrate support 108 from the chamber walls.

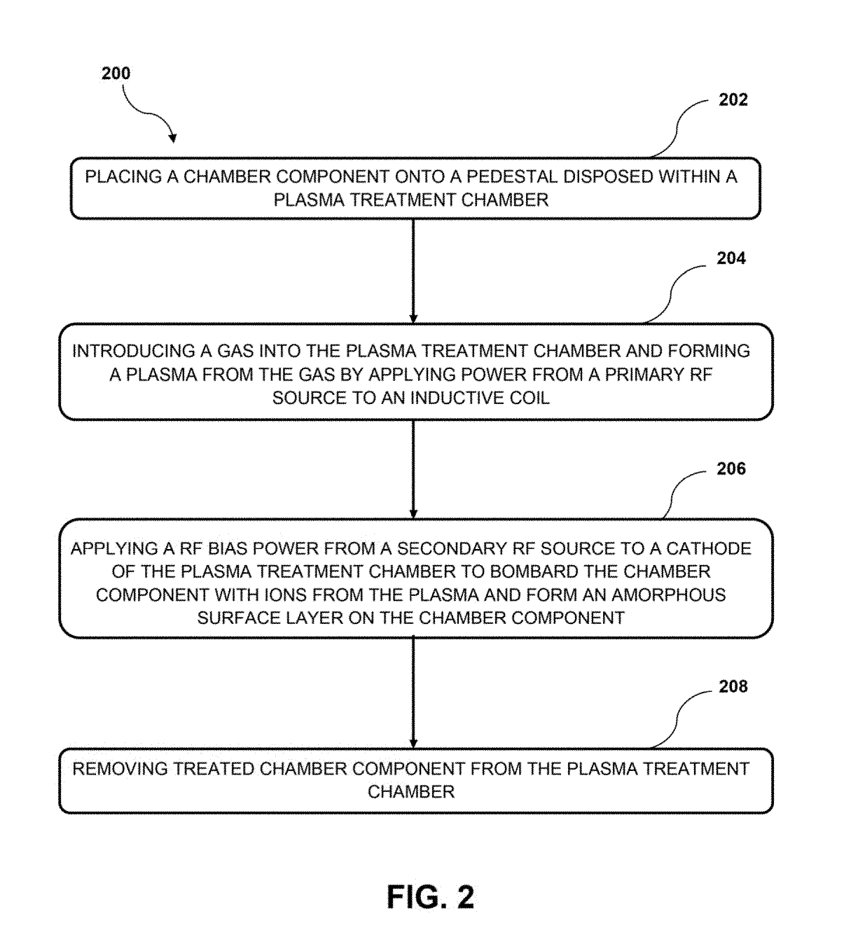

In general, the process chamber 100 includes one or more components that are exposed to plasma during processing. Each component generally includes a body having machined surfaces, including a surface facing or interfacing with a support member in the process chamber 100, and/or a surface facing the processing region 114 (“plasma facing surface”). Such components generally include chamber lid, shields, liners, showerheads, and the like. For example, the lid 118 may have a bottom surface exposing to the processing region 114 through the anode electrode 120 (which could be a showerhead). The ring assembly 104, such as a cover ring, may include a shield that has a surface interfacing with the substrate support 108 and a plasma facing surface 136 exposed to the processing region 114. The anode electrode 120 may include a surface interfacing with the lid 118 and a plasma facing surface 138 exposed to the processing region 114. The liner 106 includes a surface interfacing with the side wall 128 and a plasma facing surface 140 exposed to the processing region 114. These chamber components are treated with a surface treatment process to be discussed in FIG. 2 below to enhance surface morphology and thus reduce particle generation in the presence of the plasma.

FIG. 2 illustrate a flow chart of a method 200 for processing a chamber component according to implementations of the disclosure. Although various steps are illustrated in the drawings and described herein, no limitation regarding the order of such steps or the presence or absence of intervening steps is implied. Steps depicted or described as sequential are, unless explicitly specified, merely done so for purposes of explanation without precluding the possibility that the respective steps are actually performed in concurrent or overlapping manner, at least partially if not entirely.

The method 200 begins at block 202 by placing a chamber component onto a pedestal disposed within a plasma treatment chamber, such as the process chamber 100 of FIG. 1. The chamber component may be any components that are exposed to plasma during processing of a substrate, such as lid, shields, liners, rings, showerheads, and the like, as various components discussed above with respect to FIG. 1. In one exemplary implementation, the chamber component is a structural body that is shaped as a ring. The ring may be annular with an internal sidewall and an external sidewall. The internal sidewall may face an internal axis about which the structural body has rotational symmetry. The ring may be shaped to protect or conform to a section of a processing chamber, chamber component, or substrate within the processing chamber. For example, the chamber component can be a liner or shield that is a cylindrical member sized to fit around a substrate being processed in a processing chamber. The chamber component can also be a deposition ring, shadow ring or cover ring. In some implementations, the chamber component is a chamber lid.

The chamber component, before treatment, may have a machined surface having microcracks or peaks that can be characterized as jagged, fractured, and/or sharp. The chamber component may be made of crystalline ceramic, glass, or glass-ceramic materials, such as, for example, quartz, fused silica, silica glass, aluminum oxide, titanium oxide, silicon nitride, yttrium containing materials, yttrium oxide (Y₂O₃), yttrium-aluminum-garnet (YAG), ASMY (aluminum oxide silicon magnesium yttrium), zirconium oxide, and other such materials.

In one implementation, the chamber component is formed from crystalline ceramic material. The chamber component may be mechanically polished to a desired roughness. In another implementation, the chamber component is formed from a flame polished quartz or a non-flame polished quartz. In either case, the chamber component may be coated with a ceramic coating, such as an yttrium oxide containing ceramic or other yttrium containing oxide, in order to protect the chamber component from hydrogen containing plasma. In such case, the ceramic coating may be applied using a thermally sprayed or plasma sprayed technique. The exposed surface of the chamber component may be roughened, for example by bead blasting, prior to coating to promote better adhesion of the ceramic coating onto the exposed surface of the chamber component.

In some implementations, the chamber component and/or the ceramic coating is a high performance material (HPM) that may be produced from raw ceramic powders of Y₂O₃, Al₂O₃, ZrO₂, or any combination thereof. In one exemplary example, the chamber component and/or the ceramic coating may be formed of Y₂O₃ in a range between about 45 mol. % and about 100 mol. %, ZrO₂ in a range from about 0 mol. % and about 55 mol. %, and Al₂O₃ in a range from about 0 mol. % to about 10 mol. %. In one exemplary example, the chamber component and/or the ceramic coating may be formed of Y₂O₃ in a range between about 30 mol. % and about 60 mol. %, ZrO₂ in a range from about 0 mol. % and about 20 mol. %, and Al₂O₃ in a range from about 30 mol. % to about 60 mol. %. The chamber component and/or the ceramic coating may have a graded composition across its thickness.

The plasma treatment chamber may be a standalone chamber that is physically separated from a wafer processing chamber. The plasma treatment chamber may be any suitable vacuum chamber using inductively coupled plasma or capacitively coupled plasma. In one implementation, the plasma treatment chamber is an inductively coupled plasma chamber using an inductive cod. The plasma treatment chamber generally has a chamber wall defining a processing space therein, a pedestal having a supporting surface coated with a dielectric layer, an inductive coil located outside of the chamber wall, a primary RF source that is used to energize gas within the plasma treatment chamber, and a secondary RF source that is used to apply bias to the pedestal or the chamber component to be treated in the plasma treatment chamber. The inductive coil may be a planar coil, a cylindrical coil, or any of various other types of coils that is suitable to deliver RF power into the plasma chamber.

At block 204, a gas is introduced into the plasma treatment chamber and ignited into a plasma by applying power from the primary RF source to the inductive coil. The gas may be nitrogen (N₂), hydrogen (H₂), oxygen (O₂), neon (Ne), argon (Ar), chlorine (Cl), or any combinations thereof.

At block 206, while applying power to the inductive coil from the primary RF source, a RF bias power from the secondary RF source is supplied to a cathode electrode of the plasma treatment chamber to perform the surface treatment. The power applied to the inductive coil can be used to control plasma density, while the power applied to the cathode electrode can be used to control ion bombardment energy. The cathode electrode may be disposed within or coupled to the pedestal,

During processing, the RF bias power causes positive ions in the plasma to accelerate toward the pedestal, resulting in ion bombardment of the chamber component disposed on the pedestal. The ion bombardment of the chamber component causes the temperature of localized surface area of the chamber component to rapidly reach its melting temperature, or to reach a temperature above the crack/peak healing or melting temperature. The crystalline ceramic at surface of the chamber component is melted and reflowed to form a very smooth surface layer, which may be amorphous as opposed to the underlying crystalline structure, without any sharp edge and boundary. Melting and reflowing of the crystalline ceramic soften and heal the peaks or microcracks, resulting in a reduced internal stress on the treated surface of the chamber components. The resulting chamber component will have a thin reflowed ceramic surface layer, while the rest of the chamber component is crystalline ceramic. The surface layer may have a selected thickness between 0.1 and 50 μm, for example about 2 to 10 μm.

In operation, the power from the primary RF source (i.e., RF source power) may be applied on the range of 30 Watts to 2000 Watts, for example 200 Watts to 600 Watts, at a frequency of 10 kHz to 160 MHz, for example 13.56 MHz. The power from the secondary RF source (i.e., RF bias power) may be on the range of 20 Watts to 500 Watts, for example 100 Watts to 300 Watts, at a frequency of 10 kHz to 160 MHz, for example 13.56 MHz. The pressure within the plasma treatment chamber may be on the range of 0.5 mTorr to 100 mTorr, for example 2 mTorr. The processing time of ion bombardment may be about 10 hours to about 200 hours, for example about 15 hours to about 55 hours, such as about 15 hours to about 25 hours, about 20 hours to about 30 hours, about 35 hours to about 45 hours, about 40 hours to about 50 hours. The flow rate of the gas may be between about 10 and 500 standard cubic centimeters per minute (SCCM), for example about 30 SCCM to about 200 SCCM, which varies depending upon the type of gas used. For example, in one example where a chlorine gas is used, the flow rate may be about 15 SCCM to about 20 SCCM. In another example where an oxygen gas is used, the flow rate may be about 50 SCCM to about 100 SCCM. Using such power, pressure, and time parameters on a surface area comprising crystalline ceramic can result in the crystalline ceramic at an extremely shallow depth (e.g., less than 10 μm) to melt and reflow, without excessively raising the bulk temperature of the chamber component. It is contemplated that the process parameters discussed herein is also applicable to any chamber component made from other materials discussed in this disclosure.

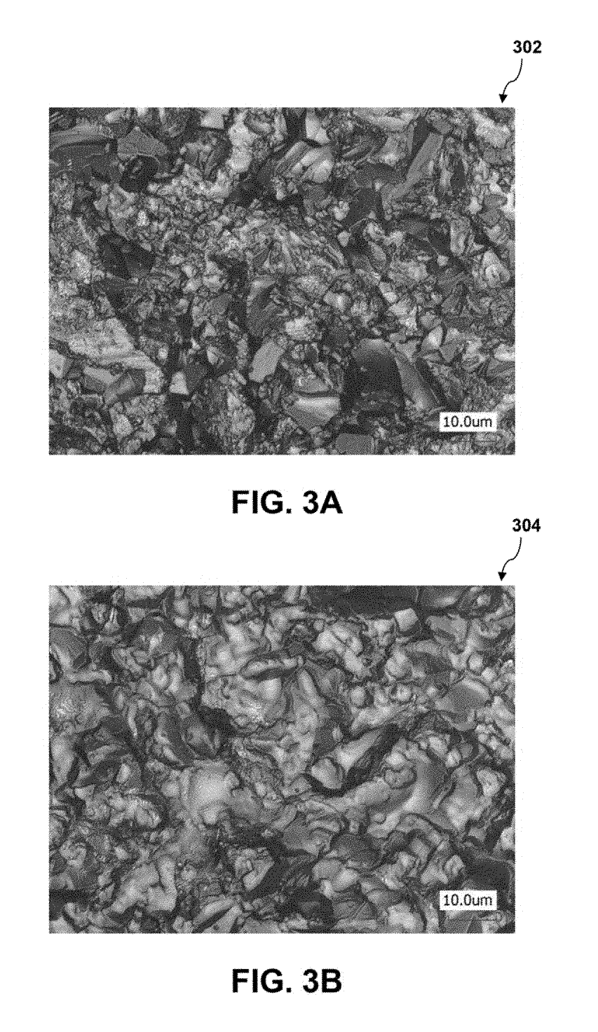

FIG. 3A shows a laser microscope (LM) image 302 of a surface of a chamber lid comprising crystalline ceramic prior to surface treatment in the plasma treatment chamber. The untreated surface includes jagged, fractured, and/or sharp peaks. FIG. 3B shows a LM image 304 of an ion bombardment treated surface of the chamber lid. As shown, the treated area of the plasma facing surface exhibits a very smooth surface without any sharp edge and boundary, i.e., the treated surface has flatter peaks as compared to the post-machined, untreated surface shown in FIG. 3A.

At block 208, the chamber component that is treated to reduce or heal peaks or microcracks is removed from the plasma treatment chamber. After completion of method 200, the treated chamber component can be used in a wafer processing chamber, such as the process chamber 100 schematically illustrated in FIG. 1.

Benefits of the present disclosure include particle reduction in a wafer processing chamber by pre-treating plasma facing surfaces of a chamber component in an inductively coupled plasma chamber. During the surface treatment, an RF bias power is applied to a pedestal on which the chamber component is placed to cause positive ions in the plasma to accelerate toward the pedestal, resulting in ion bombardment of the chamber component. The surface region of the chamber component is melted and reflowed to form a reflowed surface layer as a result of ion bombardment. The treated surface of the chamber component exhibits no sharp edge and boundary as well as reduced internal stress. As a result, the chamber component generates fewer particles during processing, thereby reducing contamination of the semiconductor wafer in wafer processing chamber.

While the foregoing is directed to implementations of the present disclosure, other and further implementations of the disclosure may be devised without departing from the basic scope thereof.

1. A component for use in a process chamber, comprising:
a crystalline body comprising machined surfaces facing a processing region of the process chamber, wherein the machined surfaces comprises at least a reflowed surface layer formed in a plasma treatment chamber by:
placing the body on a pedestal disposed within the plasma chamber;
maintaining a pressure in the plasma chamber at 0.5 mTorr to 100 mTorr;
flowing a gas into the plasma chamber at a flow rate of 10 sccm to 500 sccm;
applying an RF power to an inductive coil of the plasma chamber to form a plasma from the gas in the plasma chamber, wherein the RF power is applied on the range of 300 Watts at a frequency of 10 kHz to 160 MHz; and
while applying the RF power to the inductive coil, applying an RF bias power to the pedestal to bombard the body with ions from the plasma, wherein the RF bias power is applied on the range of 30 to 500 Watts at a frequency of 10 kHz to 160 MHz, and the body is bombarded with ions for about 10 hours to about 100 hours.

2. The component of claim 1, wherein the crystalline body is a shield, a showerhead, a chamber lid, a ring, or a liner to be disposed in the process chamber.

3. The component of claim 1, wherein the crystalline body comprises crystalline ceramic.

4. The component of claim 1, wherein the crystalline body comprises Y₂O₃, Al₂O₃, ZrO₂, or any combination thereof.

5. The component of claim 4, wherein the Y₂O₃ is in a range between about 45 mol. % and about 100 mol. %, the ZrO₂ is in a range from about 0 mol. % and about 55 mol. %, and the Al₂O₃ is in a range from about 0 mol. % to about 10 mol. %.

6. The component of claim 4, wherein the Y₂O₃ is in a range between about 30 mol. % and about 60 mol. %, the ZrO₂ is in a range from about 0 mol. % and about 20 mol. %, and the Al₂O₃ is in a range from about 30 mol. % to about 60 mol. %.

7. The component of claim 1, wherein the gas comprises nitrogen (N₂), hydrogen (H₂), oxygen (O₂), neon (Ne), argon (Ar), chlorine (CD, or any combinations thereof.

8. The component of claim 1, wherein the amorphous surface layer has a thickness between 0.1 and 50 μm.

9. A method of fabricating a component for use in a process chamber, comprising:
providing a crystalline body onto a pedestal disposed within a plasma chamber, the body having a first machined surface to interface a component of the process chamber and a second machined surface facing a processing region of the process chamber;
maintaining a pressure in the plasma chamber at 0.5 mTorr to 100 mTorr;
flowing a gas into the plasma chamber at a flow rate of 10 sccm to 500 sccm;
applying an RF power to an inductive coil of the plasma chamber to form a plasma from the gas in the plasma chamber, wherein the RF power is applied on the range of 100 Watts to 2000 Watts at a frequency of 10 kHz to 60 MHz; and
while applying the RF power to the inductive coil, applying an RF bias power to the pedestal to bombard the body with ions from the plasma so that a portion at surface of the crystalline body is melted and reflowed to form a reflowed surface layer, wherein the RF bias power is applied on the range of 20 Watts to 500 Watts at a frequency of 10 kHz to 60 MHz, and the body is bombarded with ions for about 10 hours to about 100 hours.

10. The method of claim 9, wherein the crystalline body is a shield, a showerhead, a chamber lid, a ring, or a liner to be disposed in the process chamber.

11. The method of claim 9, wherein the crystalline body comprises crystalline ceramic.

12. The method of claim 9, wherein the crystalline body comprises Y₂O₃, Al₂O₃, ZrO₂, or any combination thereof.

13. The method of claim 12, wherein the Y₂O₃ is in a range between about 45 mol. % and about 100 mol. %, the ZrO₂ is in a range from about 0 mol. % and about 55 mol. %, and the Al₂O₃ is in a range from about 0 mol. % to about 10 mol. %.

14. The method of claim 12, wherein the Y₂O₃ is in a range between about 30 mol. % and about 60 mol. %, the ZrO₂ is in a range from about 0 mol. % and about 20 mol. %, and the Al₂O₃ is in a range from about 30 mol. % to about 60 mol. %.

15. The method of claim 9, wherein the gas comprises nitrogen (N₂), hydrogen (H₂), oxygen (O₂), neon (Ne), argon (Ar), chlorine (Cl), or any combinations thereof.

16. The method of claim 9, wherein the reflowed surface layer has a thickness between 0.1 and 50 μm.

17. A method of fabricating a component for use in a semiconductor process chamber, comprising:
bombarding machined surfaces of a crystalline body disposed on a pedestal with ions from a plasma in a plasma chamber to melt a portion at surface of the crystalline body to form a reflowed surface layer having a thickness of about 0.1 μm to 50 μm, wherein the bombarding machined surfaces of the crystalline body with ions is performed by:
maintaining a pressure in the plasma chamber at range of 0.5 to 100 mTorr;
flowing a gas into the plasma chamber at a flow rate of 10 sccm to 500 sccm;
applying an RF source power on the range of 100 to 2000 Watts at a frequency of 10 kHz to 160 MHz to form a plasma from the gas; and
applying an RF bias power on the range of 20 to 500 Watts at a frequency of 10 kHz to 160 MHz to the pedestal for about 10 hours to about 200 hours.

18. The method of claim 17, wherein the crystalline body is a shield, a showerhead, a chamber lid, a ring, or a liner to be disposed in the semiconductor process chamber.

19. The method of claim 17, wherein the crystalline body comprises crystalline ceramic.

20. The method of claim 17, wherein the crystalline body comprises Y₂O₃, Al₂O₃, ZrO₂, or any combination thereof.
